(19) United States
(12) Patent Application Publication
(10) Pub. No.: US 2025/0331236 A1
(43) Pub. Date: Oct. 23, 2025

(54) NANOSHEET TRANSISTORS WITH REDUCED SUB-CHANNEL LEAKAGE AND THE METHODS OFFORMING THE SAME

(71) Applicant: Taiwan Semiconductor Manufacturing Co., Ltd., Hsinchu (TW)

(72) Inventors: Ching-Pai Hsu, New Taipei City (TW); Chi-Ruei Yeh, New Taipei City (TW); Tsung-Yu Chiang, New Taipei City (TW)

(21) Appl. No.: 19/259,978

(22) Filed: Jul. 3, 2025

Related U.S. Application Data
(63) Continuation of application No. 18/762,076, filed on Jul. 2, 2024.
(60) Provisional application No. 63/570,317, filed on Mar. 27, 2024.

(51) Int. Cl. H10D 30/67; H10D 30/01; H10D 30/43; H10D 62/10; H10D 62/13; H10D 64/01; H10D 84/01; H10D 84/03; H10D 84/83

(52) U.S. Cl. CPC H10D 30/6735; H10D 30/014; H10D 30/43; H10D 30/6757; H10D 62/121; H10D 62/151; H10D 64/017; H10D 84/0128; H10D 84/013; H10D 84/038; H10D 84/83

(57) ABSTRACT

A method includes depositing a multilayer stack including a plurality of sacrificial layers and a plurality of semiconductor layers located alternatingly. The plurality of sacrificial layers include a bottom sacrificial layer having a first thickness, and upper sacrificial layers over the bottom sacrificial layer. The upper sacrificial layers have second thicknesses smaller than the first thickness. The method further includes patterning the multilayer stack to form a protruding fin, forming a dummy gate stack on the protruding fin, forming a source/drain region aside of the dummy gate stack, removing the dummy gate stack and the plurality of sacrificial layers in the protruding fin to leave recesses, and forming a replacement gate stack in the recesses.

### PRIORITY CLAIM AND CROSS-REFERENCE

This application is a continuation of U.S. patent application Ser. No. 18/762,076, filed on Jul. 2, 2024, which application claims the benefit of the following provisionally filed U.S. patent application: Application No. 63/570,317, filed on Mar. 27, 2024, and entitled “NANOSHEET SEMICONDUCTOR DEVICE,” which applications are hereby incorporated herein by reference.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Gate-All-Around (GAA) Transistors have been introduced to replace planar transistors. The structures of the GAA transistors and methods of fabricating the GAA transistors are being developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 4 and FIGS. 5A-1, 5A-2, 5B-1, 5B-2 through FIGS. 12A-1, 12A-2, 12B-1, and 12B-2 illustrate the views of intermediate stages in the formation of Gate-All-Around (GAA) transistors in accordance with some embodiments.

FIG. 13 illustrates a process flow for forming transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Gate-All-Around (GAA) transistors, which may be nanosheet transistors and/or nanowire transistors, are formed. In accordance with some embodiments, a bottom spacing between a bottom nanostructure and the underlying semiconductor strip (sub-channel) is greater than the upper spacings between the overlying neighboring (semiconductor) nanostructures. Accordingly, it is possible to fill the bottom spacing with a first work-function layer and a second work-function layer on the first work-function layer. The second work-function layer has the function of increasing the threshold voltage of the sub transistor that includes the sub-channel. The upper spacings may be filled with portions of the gate stack, and do not include the second work-function layer. The leakage current through the sub-channel is thus reduced when the GAA transistor is turned off.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

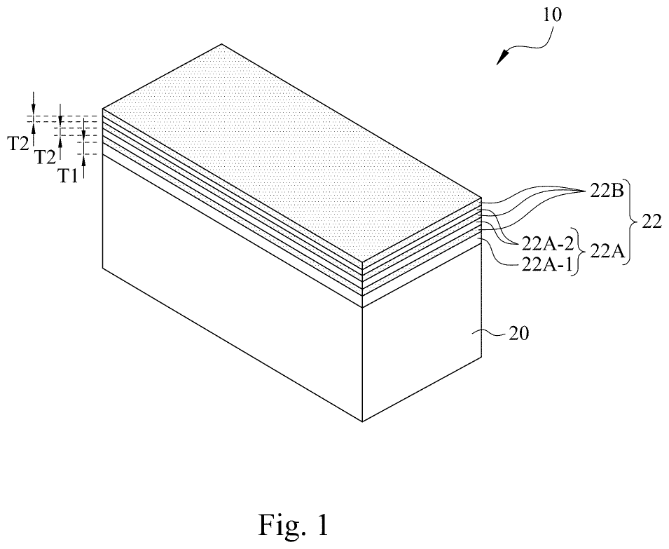

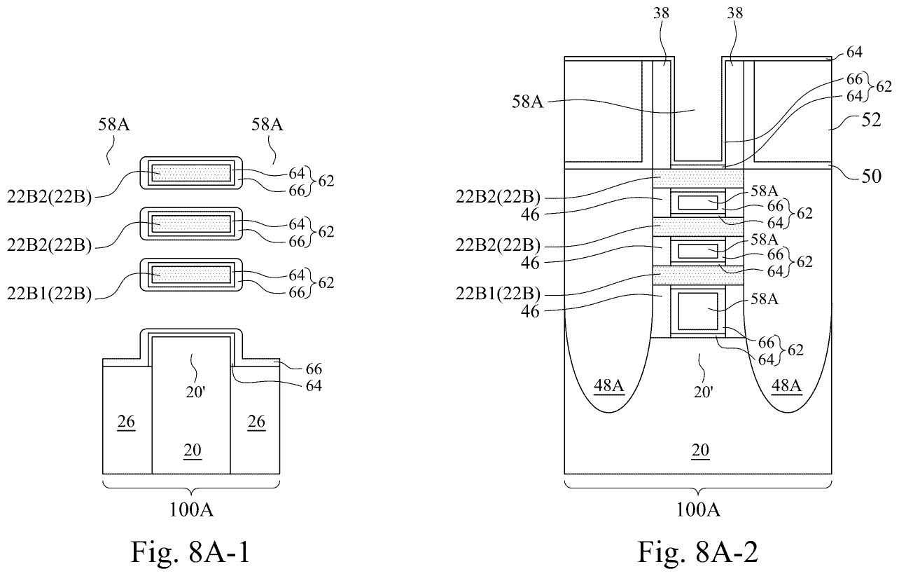

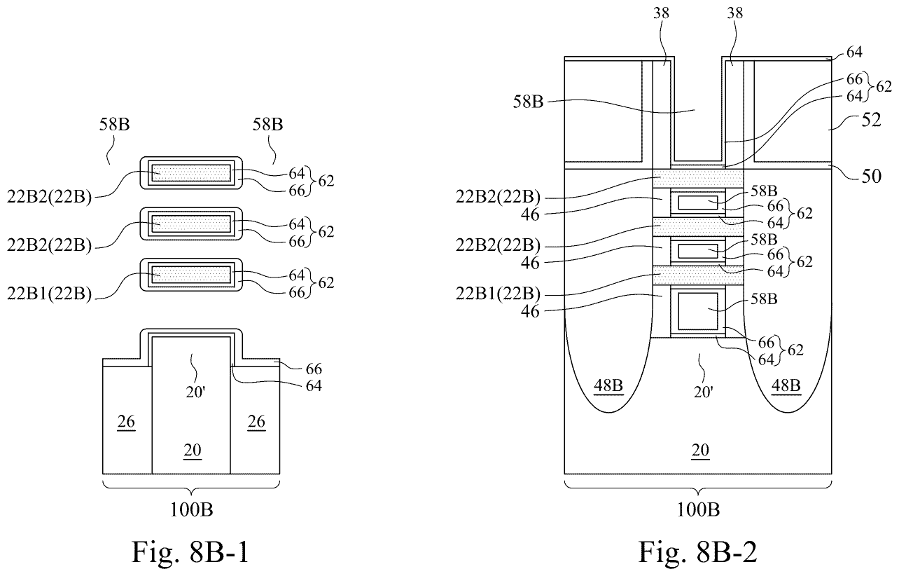

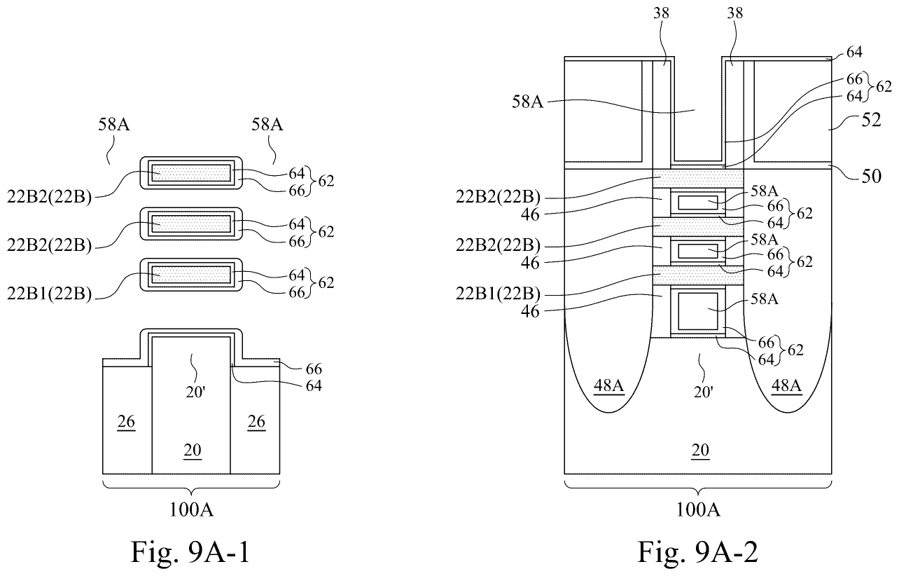

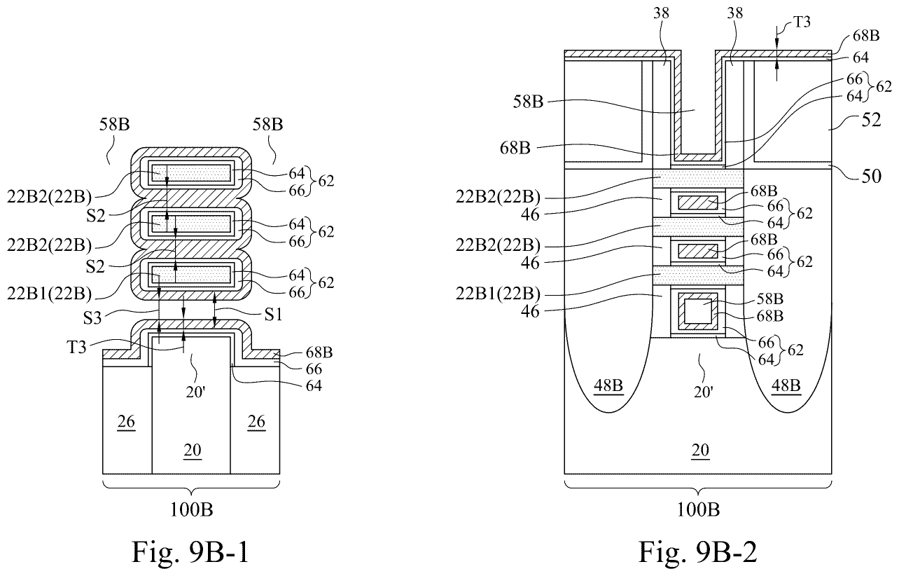

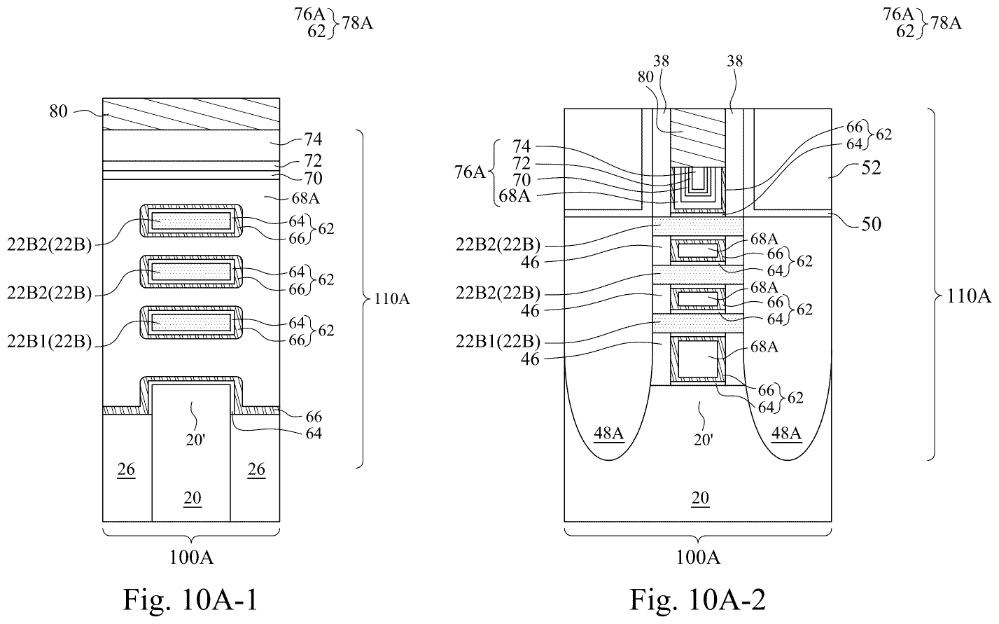

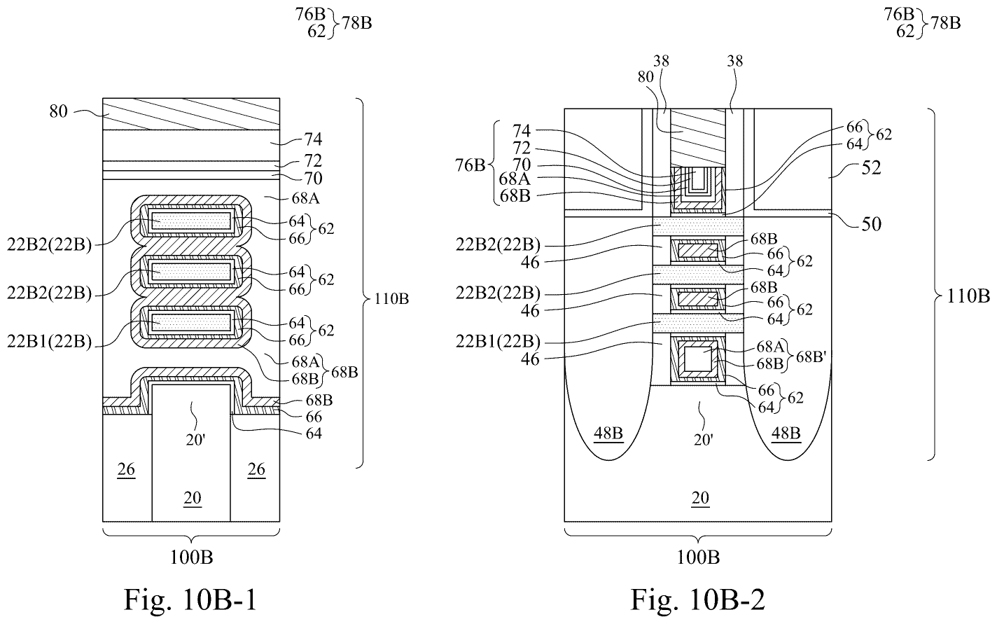

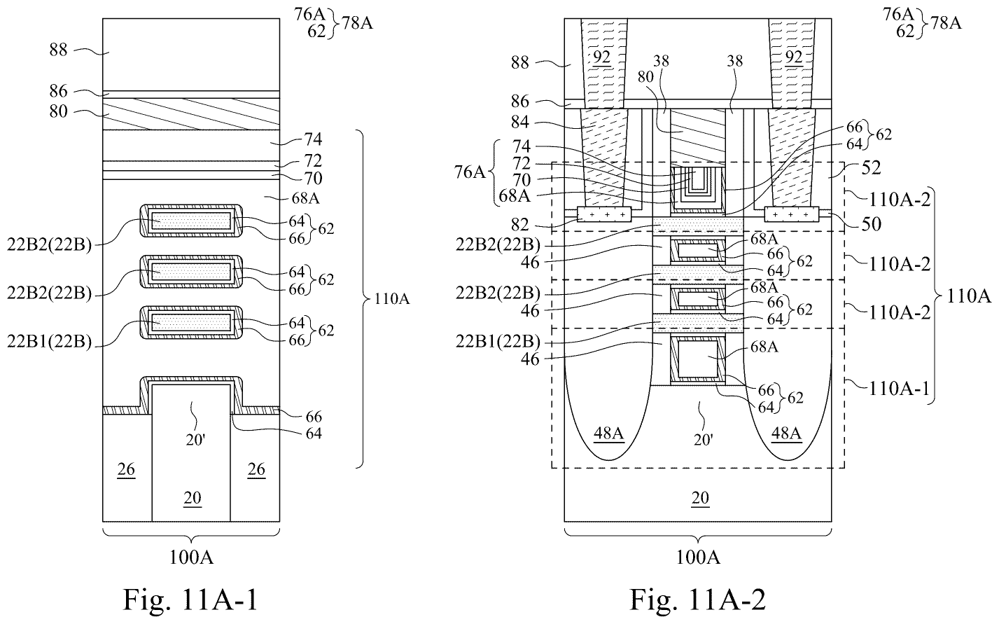

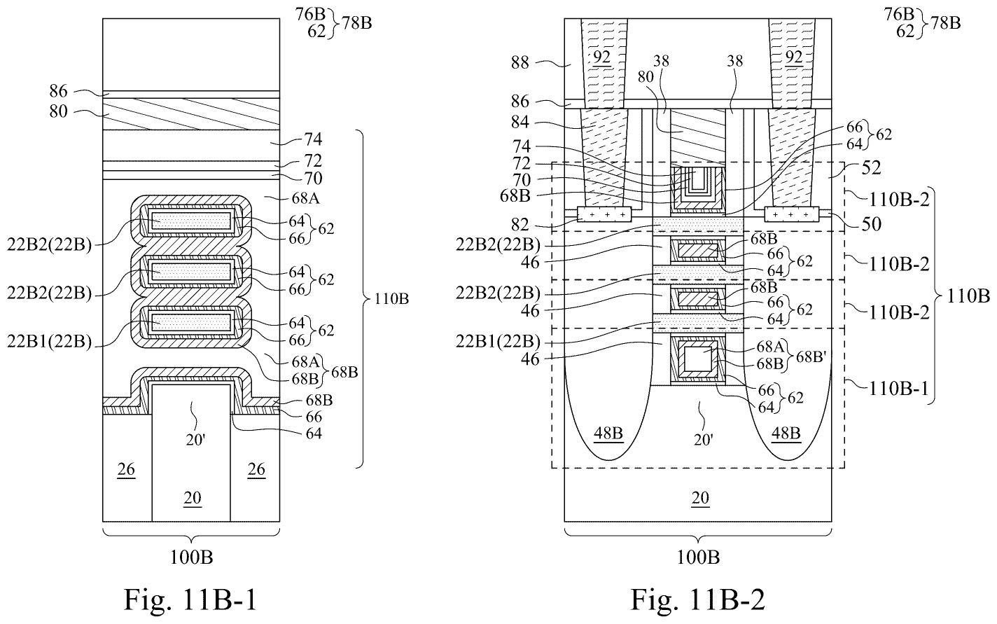

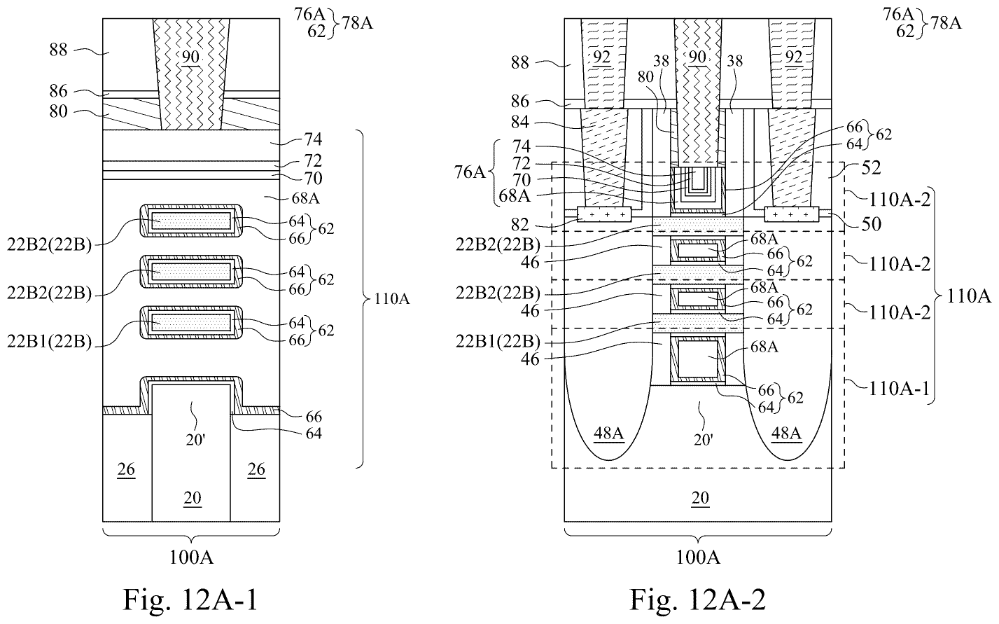

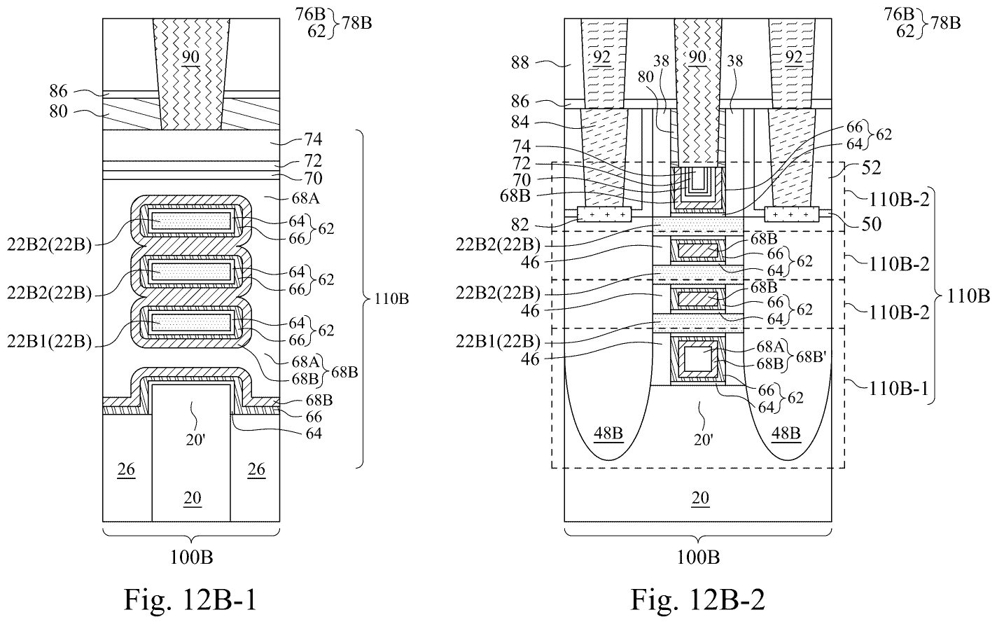

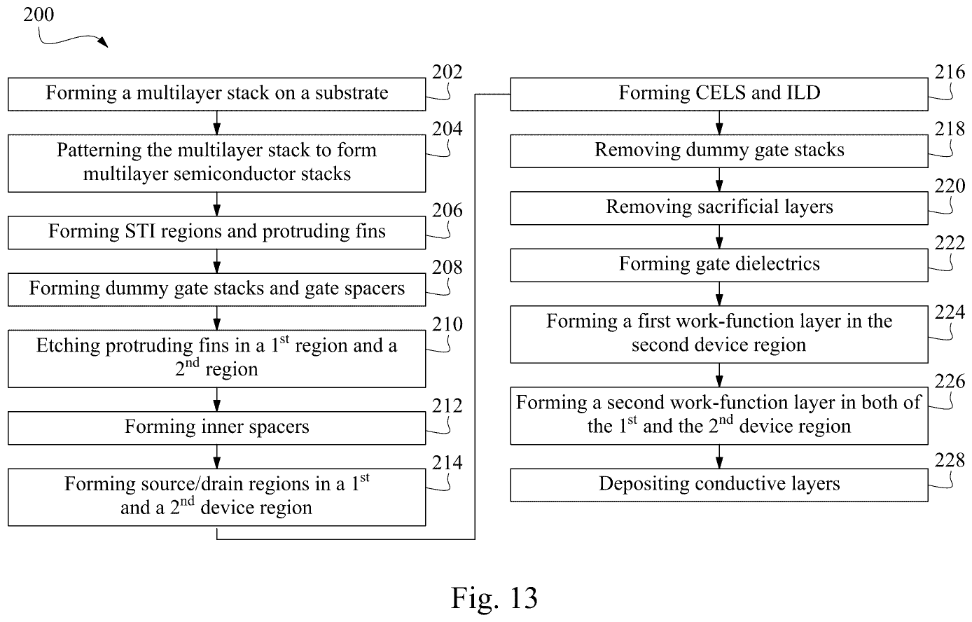

FIGS. 1 through FIGS. 12A-1, 12A-2, 12B-1, and 12B-2 illustrate the cross-sectional views of intermediate stages in the formation of a Gate-All-Around (GAA) transistors in accordance with some embodiments of the present disclosure. The corresponding processes are also reflected schematically in the process flow shown in FIG. 13.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 shown in FIG. 13. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the first layer 22A is formed to a first thickness in the range between about 9 nm and about 10 nm. However, any suitable thickness may be utilized while remaining within the scope of the embodiments.

Once the second layer 22B has been formed over the first layer 22A, the deposition process is repeated to form the remaining layers in multilayer stack 22, until a desired topmost layer of multilayer stack 22 has been formed.

In accordance with some embodiments, the bottommost layers 22A (denoted as 22A-1) has a thickness T1, and the upper layers 22A (denoted as 22A-2) have thicknesses T2. The thicknesses T2 of the upper layers 22A-2 may be the same or different from each other. Thickness T1 is greater than thickness T2. The ratio T1/T2 may be in the range between about 1.2 and about 2.0, and may be in the range between about 1.5 and 1.8. In accordance with some embodiments, thickness T1 may be in the range between about 13.5 nm and about 15 nm, and thicknesses T2 may be in the range between about 9 nm and about 10 nm. Second layers 22B may also have the same thicknesses as, or different thicknesses from, that of first layers 22A-2. In accordance with some embodiments, first layers 22A are removed in the subsequent processes, and are alternatively referred to as sacrificial layers 22A throughout the description.

In accordance with some embodiments, there may be some pad oxide layer(s) and hard mask layer(s) (not shown) formed over multilayer stack 22. These layers are patterned, and are used for the subsequent patterning of multilayer stack 22.

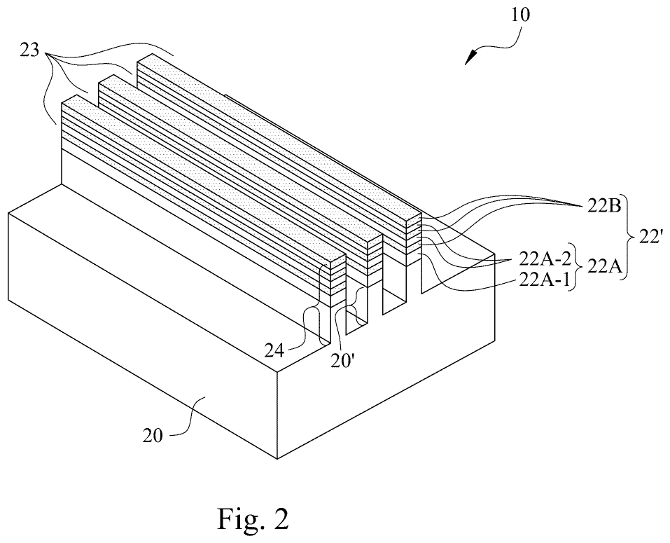

Referring to FIG. 2, multilayer stack 22 and a portion of the underlying substrate 20 are patterned in an etching process(es), so that trenches 23 are formed. The respective process is illustrated as process 204 in the process flow 200 shown in FIG. 13. Trenches 23 extend into substrate 20. The remaining portions of multilayer stacks are referred to as multilayer stacks 22′ hereinafter. Underlying multilayer stacks 22′, some portions of substrate 20 are left, and are referred to as semiconductor strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying semiconductor strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

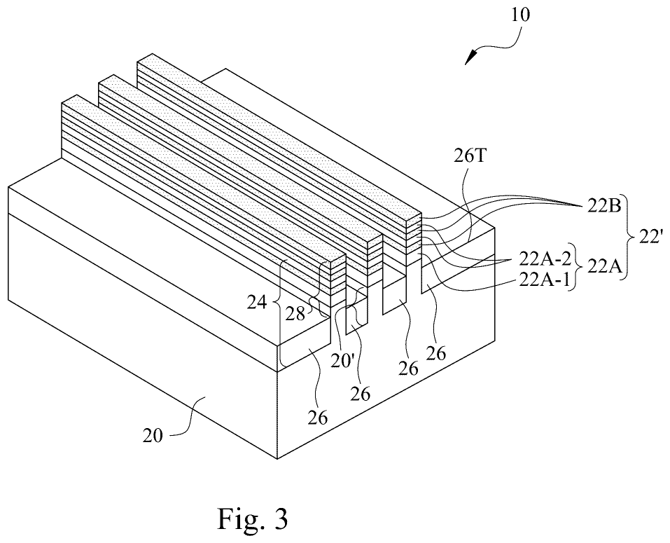

FIG. 3 illustrates the formation of isolation regions 26, which are also referred to as Shallow Trench Isolation (STI) regions throughout the description. The respective process is illustrated as process 206 in the process flow 200 shown in FIG. 13. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of semiconductor strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

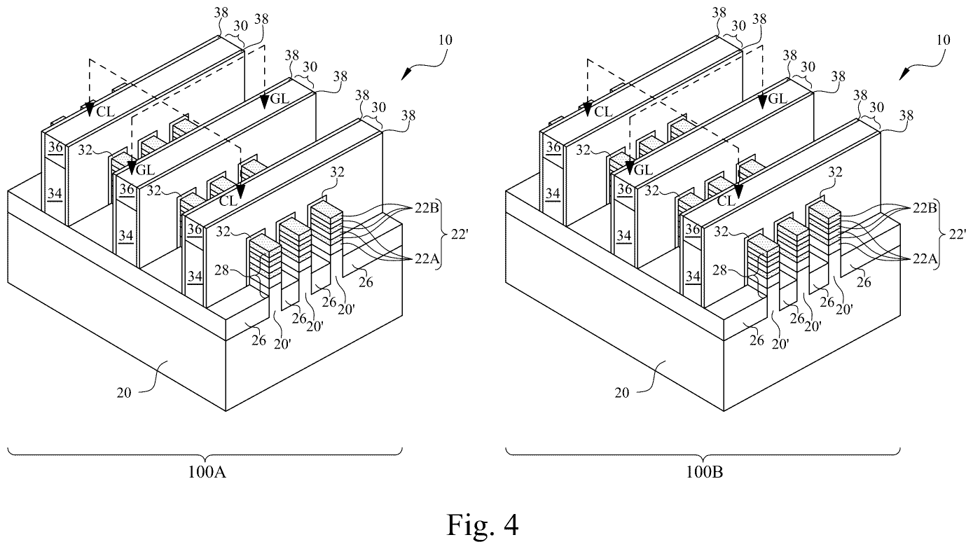

Next, FIG. 4 illustrates two device regions 100A and 100B in the same wafer 10 and same device die, with both also being used for forming GAA transistors, which may be nanosheet transistors or nanowire transistors. The structures formed in device regions 100A and 100B may share same formation processes including the processes as shown in FIGS. 1 through 3. The width of the multilayer stacks 22′ in device region 100A may be equal to, greater than, or smaller than, the width of the multilayer stacks 22′ in device region 100B.

In accordance with some embodiments, device region 100A is an n-type device region (in which a n-type transistor is to be formed), and device region 100B is a p-type device region (in which a p-type transistor is to be formed). In accordance with alternative embodiments, device region 100A is a p-type device region, and device region 100B is an n-type device region. In accordance with yet alternative embodiments, either both of device regions 100A and 100B are n-type device regions, or both of device regions 100A and 100B are p-type device regions. In the following discussed examples, it may be assumed that the device regions 100A and 100B are n-type device region and a p-type device region, respectively, while each of the device regions 100A and 100B may be another type of device region in any combination.

As shown in FIG. 4, dummy gate stacks 30 and gate spacers 38 are formed on the top surfaces and the sidewalls of (protruding) fins 28. The respective process is illustrated as process 208 in the process flow 200 shown in FIG. 13. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

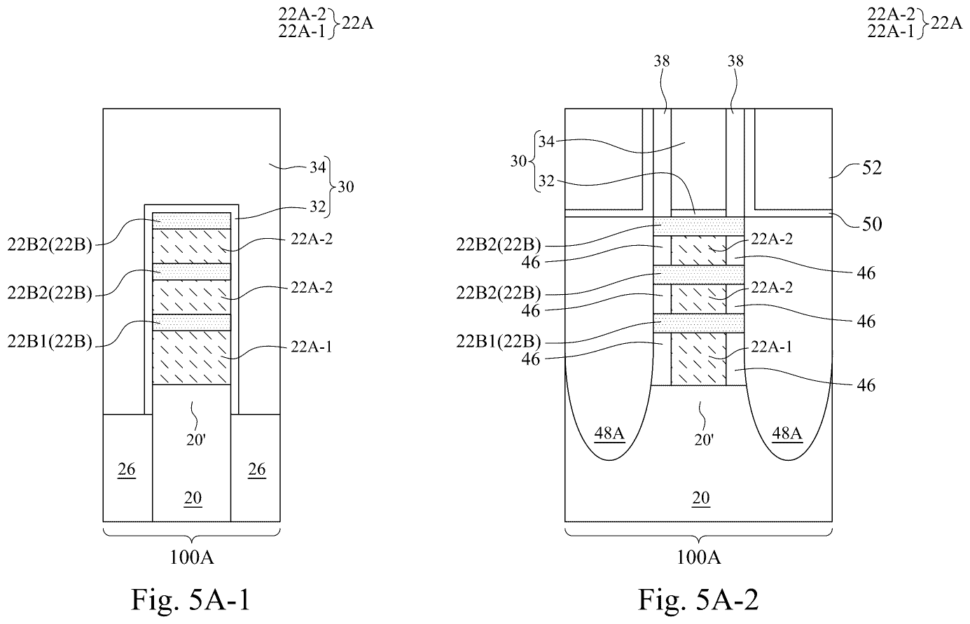

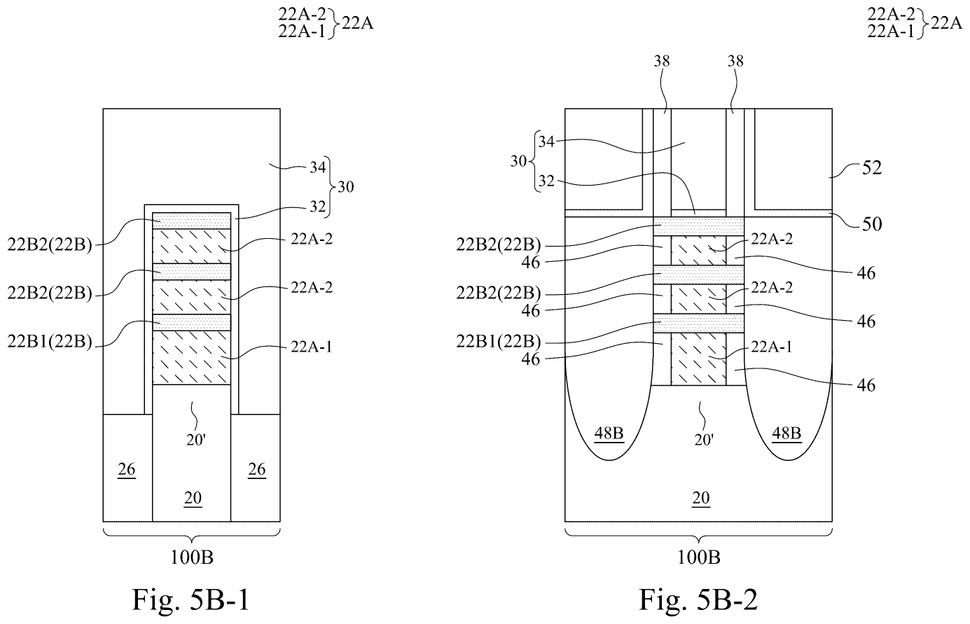

FIGS. 5A-1 and 5A-2 illustrate the cross-sectional views of the structures after the subsequent formation of source/drain regions and overlying dielectric layers in the device region 100A in FIG. 4. FIGS. 5B-1 and 5B-2 illustrate the cross-sectional views of the structures after the subsequent formation of source/drain regions and overlying dielectric layers in the device region 100B in FIG. 4. Throughout the description, the figures with the figure numbers including “A-1” or “A-2” are obtained from the device region 100A, and are obtained from the cross-sections GL-GL and CL-CL, respectively. The figures with the figure numbers including “B-1” or “B-2” are obtained from the device region 100B in FIG. 4, and are obtained from the cross-sections GL-GL and CL-CL, respectively. For example, FIG. 5A-1 illustrates the reference cross-section GL-GL (with “GL” representing Gate-Length) in FIG. 4, which reference cross-section is parallel to the gate lengthwise direction. FIG. 5A-2 illustrates the reference cross-section CL-CL (with “CL” representing Channel-Length) in FIG. 4, which cross-section cuts through a protruding fin 28.

Referring to FIGS. 5A-2 and 5B-2, the portions of protruding fins 28 (FIG. 4) that are not directly underlying dummy gate stacks 30 and gate spacers 38 are recessed through an etching process to form recesses (occupied by regions 48A and 48B). The respective process is illustrated as process 210 in the process flow 200 shown in FIG. 13. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying semiconductor strips 20′. The bottoms of the recesses are at least level with, or may be lower than the bottoms of multilayer semiconductor stacks 22′. The etching may be anisotropic, so that the sidewalls of multilayer semiconductor stacks 22′ facing recesses 42 are vertical and straight.

Inner spacers 46 are then formed. The respective process is illustrated as process 212 in the process flow 200 shown in FIG. 13. The formation process may include laterally recessing sacrificial layers 22A through etching, and filling the resulting lateral recesses with a dielectric material such as SiO₂, SiOC, SiON, SiOCN, or the like.

FIG. 5A-2 further illustrates the formation of source/drain regions 48A in device region 100A, and FIG. 5B-2 further illustrates the formation of source/drain regions 48B in device region 100B. Source/drain region(s) may refer to a source or a drain, individually or collectively dependent upon the context. The respective process is illustrated as process 214 in the process flow 200 shown in FIG. 13. Source/drain regions 48A and 48B may extend lower than the bottom nanostructure 22B by a distance in a range between about 50 nm and about 55 nm.

The source/drain regions 48A and 48B, when being n-type regions, may comprise silicon or SiC and an n-type dopant such as As, P, Sb, or the like, or combinations thereof. For example, source/drain regions 48A and 48B, when being n-type, may comprise SiAs, SiP, SiCP, SiAsP, SiSb, or the like. The source/drain regions 48A and 48B, when being p-type regions, may comprise silicon, SiGe, or Ge, and further include a p-type dopant such as boron, indium, or combinations thereof. For example, the source/drain regions 48A and 48B, when being p-type, may comprise SiGeB, GeB, or the like.

The formation of source/drain regions 48A and 48B may be performed through epitaxy processes. Furthermore, when source/drain regions 48A and 48B are of the same conductivity type, source/drain regions 48A and 48B may be epitaxially grown through the same epitaxy processes. In an example embodiment in which device region 100A and 100B are an n-type device region and a p-type device region, respectively, source/drain regions 48A are n-type regions, and source/drain regions 48B are p-type regions.

FIGS. 5A-1, 5A-2, 5B-1 and 5B-2 further illustrate the formation of Contact Etch Stop Layer (CESL) 50 and Inter-Layer Dielectric (ILD) 52. The respective process is illustrated as process 216 in the process flow 200 shown in FIG. 13. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be a silicon oxide, Phospho-Silicate Glass (PSG), Boro-Silicate Glass (BSG), Boron-Doped Phospho-Silicate Glass (BPSG), Undoped Silicate Glass (USG), or the like.

A planarization process such as a CMP process or a mechanical grinding process is performed to level the top surface of ILD 52. In accordance with some embodiments, the planarization process may remove hard masks 36 to reveal dummy gate electrodes 34, or may be stopped on, hard masks 36. In accordance with some embodiments, after the planarization process, the top surfaces of dummy gate electrodes 34 (or hard masks 36), gate spacers 38, and ILD 52 are level within process variations.

Referring to FIGS. 6A-1, 6A-2, 6B-1 and 6B-2, the dummy gate electrodes 34 (and hard masks 36, if remaining) and dummy gate dielectric 32 in device regions 100A and 100B are removed in one or more etching processes, so that recesses 58A and 58B (collectively referred to as recesses 58) are formed in device regions 100A and 100B, respectively. The respective process is illustrated as process 218 in the process flow 200 shown in FIG. 13. Multilayer stacks 22′ are exposed to recesses 58A and 58B.

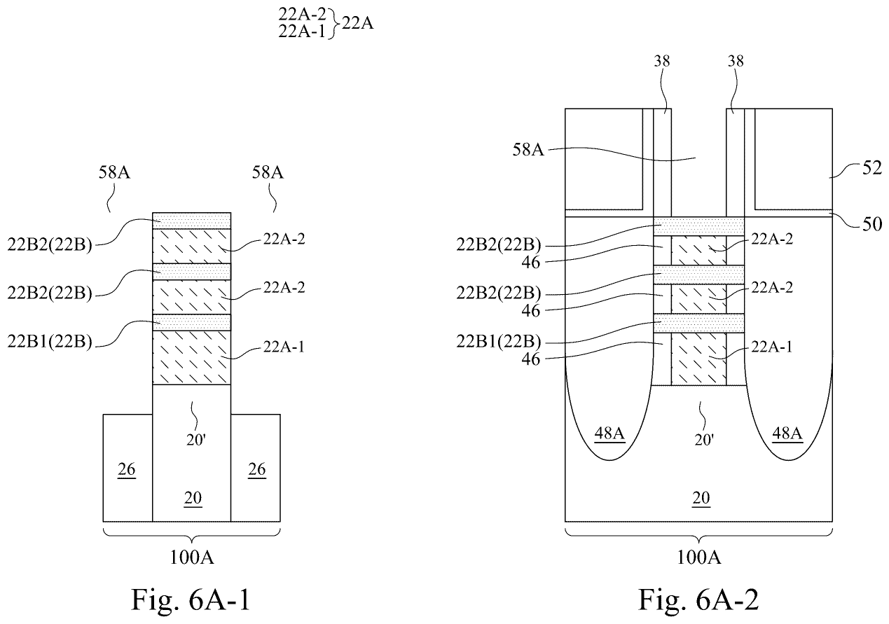

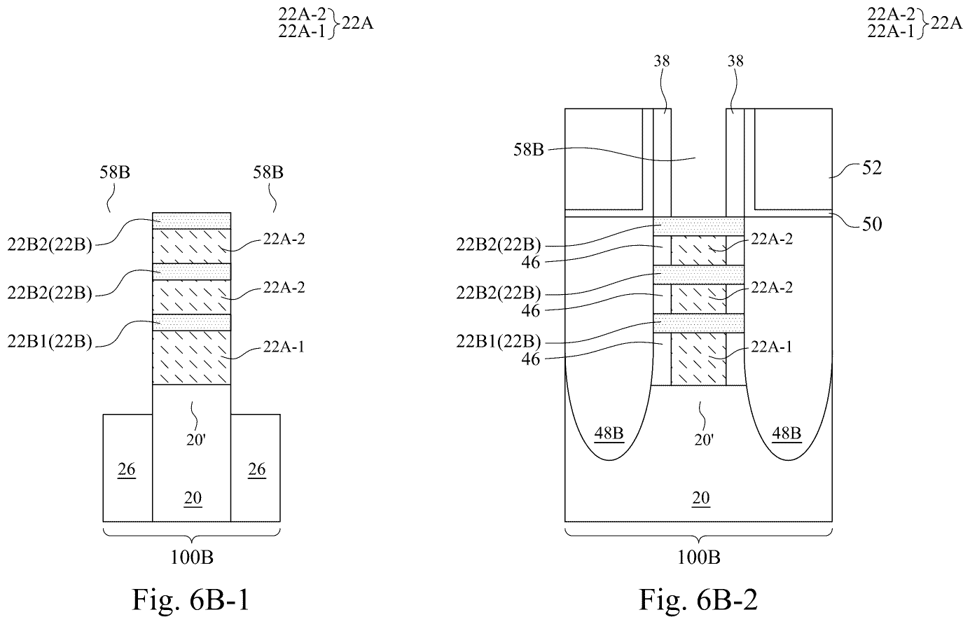

Referring to FIGS. 7A-1, 7A-2, 7B-1 and 7B-2, the recesses 58A and 58B are extended downwardly between nanostructures 22B by removing sacrificial layers 22A through etching. As may be realized from FIGS. 6A-1 and 6B-1, after the removal of dummy gate dielectric 32 and dummy gate electrode 34, the sidewalls of sacrificial layers 22A are exposed, and thus sacrificial layers 22A can be removed. The respective process is illustrated as process 220 in the process flow 200 shown in FIG. 13.

Due to the difference between thicknesses T1 and T2 (FIG. 1) of the bottom sacrificial layer 22A-1 and upper sacrificial layers 22A-2, the spacing S1 between semiconductor strip 20′ and the overlying bottommost nanostructure 22B is equal to or slightly different from (due to etching process) thickness T1. The spacings S2 between the neighboring nanostructures 22B is equal to or slightly different from (due to etching process) thicknesses T2, which is smaller than thickness T1. The ratio S1/S2 may be in the range between about 1.2 and 2.0 in accordance with some embodiments.

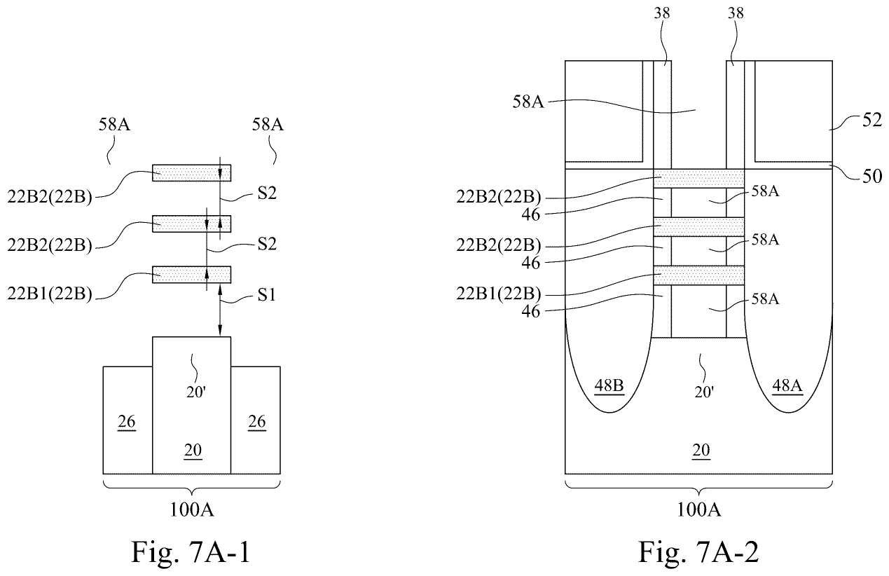

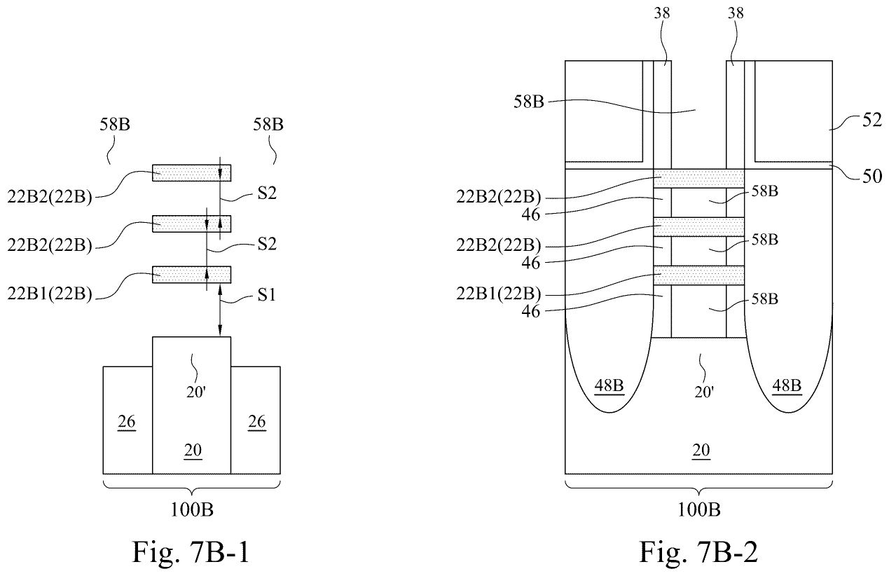

Referring to FIGS. 8A-1, 8A-2, 8B-1 and 8B-2, gate dielectrics 62 are formed. The respective process is illustrated as process 222 in the process flow 200 shown in FIG. 13. In accordance with some embodiments, each of gate dielectrics 62 includes an interfacial layer 64 and a high-k dielectric layer 66 on the interfacial layer 64. Interfacial layer 64 may have a thickness in the range between about 1 nm and about 1.5 nm. The thickness of interfacial layer 64 may also be smaller than ⅓ of the spacing S2 (FIGS. 7A-1 and 7B-1). In accordance with some embodiments, the gate dielectrics 62 in device regions 100A and 100B are formed sharing common formation processes. The interfacial layer 64 may be formed of or comprise silicon oxide, which may be deposited through a conformal deposition process such as ALD or CVD. Interfacial layer 64 may also be formed through an oxidation process.

In accordance with some embodiments, the high-k dielectric layer 66 comprises one or more dielectric layers. For example, high-k dielectric layer 66 may include a metal oxide or a silicate of hafnium, aluminum, zirconium, lanthanum, manganese, barium, titanium, lead, and combinations thereof. The high-k dielectric layer 66 may also be deposited through a conformal deposition process such as ALD or CVD. High-k dielectric layer 66 may have a thickness in the range between about 1 nm and about 1.5 nm, which thickness may be substantially the same as the thickness of interfacial layer 64.

Referring to FIGS. 9B-1 and 9B-2, which illustrate the views in device region 100B, a first work-function layer 68B is formed. The respective process is illustrated as process 224 in the process flow 200 shown in FIG. 13. In accordance with some embodiments in which a p-type transistor is being formed in device region 100B, work-function layer 68B may be a p-type work-function layer having a work function higher than mid-gap work function (about 4.5 eV to about 4.6 eV). For example, the work function of work-function layer 68B may be in the range between about 4.6 eV and about 5.2 eV. In accordance with some embodiments, work-function layer 68B may be formed of or comprises TIN, TiC, TiCN, or the like.

In accordance with alternative embodiments, work-function layer 68B may have a mid-gap work function, for example, in the range between about 4.5 eV and about 4.6 eV. The corresponding work-function layer 68B may comprise tungsten. The formation process may include ALD, CVD, or the like.

In accordance with some embodiments, the work-function layer 68B is deposited conformally on the high-k dielectric layers 66. The thickness T3 of work-function layer 68B may be greater than T2/2 and smaller than T1/2 (FIG. 1). For example, the thickness of work-function layer 68B may be in the range between about 3 nm and about 4.5 nm. The resulting work-function layer 68B deposited on neighboring semiconductor nanostructures 22B thus merge with each other, with no gap left in between. Between the bottom nanostructures 22B and semiconductor strip 20′, on the other hand, a gap is left. In accordance with some embodiments, the spacing S1 (which is equal to thickness T1 in FIG. 1) is greater than about 13.5 nm, and may be in the range between about 13.5 nm and about 15 nm. The remaining spacing S3 may be greater than about 1 nm, and may be in the range between about 1 and about 3 nm.

FIGS. 9A-1 and 9A-2 illustrate the structure shown in device region 100A at a time after the formation of work-function layer 68B in accordance with some embodiments. The high-k dielectric layer 66 may be exposed. In accordance with some embodiments, the formation of work-function layer 68B may include a blanket conformal deposition process, so that the work-function layer 68B is also deposited into device region 100A when it is deposited into device region 100B. An etching mask (not shown) may then be formed to cover device region 100B, followed by an etching process to remove the work-function layer 68B from device region 100A, and hence re-exposing high-k dielectric layer 66. The etching mask is then removed.

FIGS. 10A-1, 10A-2, 10B-1 and 10B-2 illustrates the deposition of work-function layer 68A. The respective process is illustrated as process 226 in the process flow 200 shown in FIG. 13. The thickness of work-function layer 68A may be in the range between about 6 nm and about 7 nm. In accordance with some embodiments in which an n-type transistor is being formed in device region 100A, work-function layer 68A may have a work function lower than the mid-gap work function, and may be in the range between about 4.0 eV and about 4.5 eV. In accordance with some embodiments, work-function layer 68B may be formed of or comprise an aluminum-containing material such as TiAl, TiAlC, TiAlN, TaAl, TaAlC, TaAlN, or the like.

In accordance with alternative embodiments, work-function layer 68A may have a mid-gap work function, for example, in the range between about 4.5 eV and about 4.6 eV. The corresponding work-function layer 68A may comprise tungsten. The formation process may include ALD, CVD, or the like. Other materials such as Si, Ti, or the like may also be used.

FIGS. 10A-1, 10A-2, 10B-1 and 10B-2 further illustrate the formation of upper layers of the gate electrodes. The respective process is illustrated as process 228 in the process flow 200 shown in FIG. 13. In accordance with some embodiments, silicon layer 70, which comprises elemental silicon (rather than a compound of silicon) is deposited. The deposition may be achieved, for example, by soaking wafer 10 in a silicon-containing precursor such as silane, di-silane, or the like. The thickness of silicon layer 70 may be in the range between about 1 nm and about 2 nm. Glue layer 72, which may include TiN, is deposited on silicon layer 70. Glue layer 72 may be formed through a deposition process such as CVD, ALD, or the like. The thickness of glue layer 72 may be in the range between about 1 nm and about 3 nm, and may be in the range between about 1 nm and about 2 nm, or in the range between about 2.5 nm and about 3 nm.

A filling metal region 74 is further deposited on glue layer 72, and fully fills the remaining recesses. The deposition thickness of filling metal region 74 may be in the range between about 3 nm and about 4 nm. A planarization process such as a CMP process or a mechanical grinding process is then performed, leaving gate electrodes 76A and 76B in device regions 100A and 100B, respectively.

In device region 100A, gate dielectric 62 and gate electrode 76A collectively form gate stack 78A. In device region 100B, gate dielectric 62 and gate electrode 76B collectively form gate stack 78B. The height of gate stacks 78A and 78B may be in the range between about 12 nm and about 14 nm. GAA transistors 110A and 110B are thus formed in device regions 100A and 100B, respectively.

In device region 100A, in accordance with some embodiments, work-function layer 68A fully fills the bottom gap between nanostructure 22B1 and semiconductor strip 20′, and overlying layers such as silicon layer 70 and glue layer 72 are not filled into the bottom gap. In accordance with alternative embodiments, some other layers such as silicon layer 70, or both of silicon layer 70 and glue layer 72 are filled into the bottom gap in addition to the work-function layer 68B, while the upper gaps are fully filled by work-function layer 68A.

In device region 100B, in accordance with some embodiments, work-function layers 68A and 68B fully fill the bottom gap between nanostructure 22B1 and semiconductor strip 20′, and overlying layers such as silicon layer 70 and glue layer 72 are not filled into the bottom gap. In accordance with alternative embodiments, some other layers such as silicon layer 70, or both of silicon layer 70 and glue layer 72 are filled into the bottom gap, while the upper gaps are fully filled by work-function layer 68B. Dielectric hard masks 80 are formed over gate stacks 78A and 78B. The formation process may include recessing gate stacks 78A and 78B through etching, and filling the resulting recesses with a dielectric material. A planarization process is then performed to level the top surfaces of dielectric hard masks 80 and ILD 52.

FIGS. 11A-1, 11A-2, 11B-1, and 11B-2 and FIGS. 12A-1, 12A-2, 12B-1, and 12B-2 illustrate the formation of upper features. In accordance with some embodiments, as shown in FIGS. 11A-1, 11A-2, 11B-1, and 11B-2, source/drain silicide layers 82 are formed on source/drain regions 48A and 48B, and source/drain contact plugs 84 are formed in ILD 52. Etch stop layer 86 and ILD 88 are further formed, with source/drain contact plugs 92 being formed in etch stop layer 86 and ILD 88. The formation of source/drain contact plugs 92 includes a planarization process such as a CMP process. FIGS. 12A-1, 12A-2, 12B-1, and 12B-2 illustrate the formation of gate contact plugs 90, which penetrate through the dielectric hard masks 80 to electrically connect to gate electrodes.

In device region 100A, as shown in FIGS. 12A-1 and 12A-2, work-function layer 68A fully fills the gaps between neighboring semiconductor nanostructures 22B, and fully fills the gap between the bottom semiconductor nanostructure 22B and semiconductor strip 20′. Accordingly, the channels formed of semiconductor nanostructures 22B and the sub-channel 20′ are all controlled by gate stacks that have work-function layer 68A.

It may be considered that nanosheet transistor 110A includes two types of sub transistors. The first sub transistor 110A-1 includes sub-channel 20′ as its channel, the gate stack portion between sub-channel 20′ and semiconductor nanostructure 22B1 as its gate stack, and source/drain regions 48A as its source/drain regions. The second sub transistors 110A-2 include a plurality of semiconductor nanostructures 22B1 and 22B2 as the channels, and the respective overlying portions of gate stack 78A as the gate stacks, and further include source/drain regions 48A as their source/drain regions. The sub transistor 110A-1 and the sub transistors 110A-2 are connected in parallel to form the transistor 110A. The sub transistor 110A-1 and the sub transistors 110A-2 may have the same threshold voltage.

In device region 100B, on the other hand, as shown in FIGS. 11B-1 and 11B-2, work-function layer 68B fully fills the gaps between neighboring semiconductor nanostructures 22B2. Accordingly, the corresponding work-function layer is work-function layer 68B. Work-function layers 68B and 68A (collectively referred to as work-function layer 68B′), on the other hand, collectively fill the bottom gap between the bottom semiconductor nanostructure 22B1 and semiconductor strip 20′.

It may be considered that nanosheet transistor 110B also includes two types of sub transistors. The first sub transistor 110B-1 includes sub-channel 20′ as its channel, the gate stack portion 78B between sub-channel 20′ and the bottom semiconductor nanostructure 22B1 as its gate stack, and source/drain regions 48B as its source/drain regions. The second sub transistors 110B-2 include a plurality of semiconductor nanostructure 22B1 and 22B2 as the channels, and the respective overlying portions of gate stack 78B as their gate stacks, and source/drain regions 48B as their gate stacks. The sub transistor 110B-1 and the sub transistors 110B-2 are connected in parallel to form the transistor 110A.

In accordance with some embodiments in which work-function layer 68B has a p-type work function, for example, work function WF68B, work-function layer 68A has a work function WF68A lower than the work function WF68B. Accordingly, assuming transistor 110B is a p-type transistor, the effective work function of the gate electrode of the first sub transistor 110B-1 is lower than work function WF68B alone. The threshold voltage Vt68B1 of the sub transistor 110B-1 is thus higher than the threshold voltage Vt68B2 of the sub transistors 110B-2.

It is appreciated that the sub-channel 20′ is prone to leakage, especially when the width of the nanosheets is increased. In accordance with some embodiments, by tuning work-function layers for the gate stack portion of the sub-channel 20′, when transistor 110B is turned off, due to the higher threshold voltage Vt68B1 of the sub transistor 110B-1 than the threshold voltages Vt68B2 of the sub transistors 110B-2, the sub-channel 20′ is turned off better, and the leakage current through the sub-channel 20′ is reduced.

In accordance with some example embodiments as discussed above, transistor 110A is an n-type transistor, and transistor 110B is a p-type transistor. Accordingly, work-function layer 68B is a p-type work-function layer or a mid-gap work-function layer, and work-function layer 68A has a lower work function (which may be a p-type work-function, a mid-gap work function, or an n-type work function) than work-function layer 68B to increase the threshold voltage of the sub transistor 100B-1.

In accordance with alternative embodiments, transistor 110A is a p-type transistor, and transistor 110B is an n-type transistor. Accordingly, work-function layer 68B is an n-type work-function layer or a mid-gap work-function layer, and work-function layer 68A has a higher work function (which may be a n-type work-function, mid-gap work function, or a p-type work function) than work-function layer 68B to increase the threshold voltage of the sub transistor 100B-1.

In accordance with yet alternative embodiments, both of transistors 110A and 110B are p-type transistors. Accordingly, work-function layer 68B is a p-type work-function layer or a mid-gap work-function layer, and work-function layer 68A has a lower work function (which may be an n-type work-function or a mid-gap work function) than work-function layer 68B to increase the threshold voltage of the sub transistor 100B-1.

In accordance with yet alternative embodiments, both of transistors 110A and 110B are n-type transistors. Accordingly, work-function layer 68B is an n-type work-function layer or a mid-gap work-function layer, and work-function layer 68A has a higher work function (which may be a p-type work-function or a mid-gap work function) than work-function layer 68B to increase the threshold voltage of the sub transistor 100B-1.

The embodiments of the present disclosure have some advantageous features. By forming multiple work-function layers for the bottom portion of the gate stacks of GAA transistors, the threshold voltage of the bottom sub transistor is increased, and the leakage through sub-channels is reduced.

In accordance with some embodiments of the present disclosure, a method comprises depositing a multilayer stack comprising a plurality of sacrificial layers and a plurality of semiconductor layers located alternatingly, wherein the plurality of sacrificial layers comprise a bottom sacrificial layer having a first thickness; and upper sacrificial layers over the bottom sacrificial layer, wherein the upper sacrificial layers have second thicknesses smaller than the first thickness; patterning the multilayer stack to form a first protruding fin; forming a first dummy gate stack on the first protruding fin; forming a first source/drain region aside of the first dummy gate stack; removing the first dummy gate stack and the plurality of sacrificial layers in the first protruding fin to leave first recesses; and forming a first replacement gate stack in the first recesses.

In an embodiment, a ratio of the first thickness to one of the second thicknesses is greater than about 1.2. In an embodiment, the first recesses comprise a bottom recess below a bottommost semiconductor layer of the plurality of semiconductor layers in the first protruding fin, wherein the forming the first replacement gate stack comprises depositing a first work-function layer and depositing a second work-function layer into the bottom recess; and upper recesses higher than the bottommost semiconductor layer, wherein the first replacement gate stack comprises the first work-function layer in the upper recesses. In an embodiment, the depositing the first work-function layer results in an entirety of one of the upper recesses to be filled.

In an embodiment, the first work-function layer and the second work-function layer comprise different materials. In an embodiment, the first source/drain region is comprised in a p-type transistor, and wherein the second work-function layer has a lower work function than the first work-function layer. In an embodiment, the first work-function layer has a p-type work function, and the second work-function layer has an n-type work function. In an embodiment, the first work-function layer has a first p-type work function, and the second work-function layer has a second p-type work function lower than the first p-type work function.

In an embodiment, the first source/drain region is comprised in an n-type transistor, and wherein the second work-function layer has a higher work function than the first work-function layer. In an embodiment, the first work-function layer has an n-type work function, and the second work-function layer has an p-type work function. In an embodiment, the first work-function layer has a first n-type work function, and the second work-function layer has a second n-type work function higher than the first n-type work function.

In an embodiment, the patterning the multilayer stack further results in a second protruding fin to be formed, and the method further comprises forming a second dummy gate stack on the second protruding fin; forming a second source/drain region aside of the second dummy gate stack; removing the second dummy gate stack and the plurality of sacrificial layers in the second protruding fin to leave second recesses; and forming a second replacement gate stack in the second recesses, wherein all of the second recesses are filled with same work-function layers.

In accordance with some embodiments of the present disclosure, a structure comprises a semiconductor strip; a first isolation region and a second isolation region on opposing sides of the semiconductor strip; a plurality of semiconductor nanostructures overlapping the semiconductor strip, wherein upper ones of the plurality of semiconductor nanostructures overlap respective lower ones of the plurality of semiconductor nanostructures; a gate stack comprising a bottom portion having a first height, wherein the bottom portion is between the semiconductor strip and the plurality of semiconductor nanostructures; and upper portions between neighboring ones of the plurality of semiconductor nanostructures, wherein the upper portions have second heights smaller than the first height; and a semiconductor region aside of, and contacting, the plurality of semiconductor nanostructures.

In an embodiment, the upper portions of the gate stack have a same height. In an embodiment, the bottom portion of the gate stack comprises a first work-function layer; and a second work-function layer encircled by the first work-function layer, wherein the upper portions of the gate stack comprise the first work-function layer and are free from the second work-function layer. In an embodiment, the bottom portion further comprises a silicon layer encircled by the second work-function layer. In an embodiment, a ratio of the first height to one of the second heights is greater than about 1.2.

In accordance with some embodiments of the present disclosure, a structure comprises a plurality of semiconductor nanostructures, wherein upper ones of the plurality of semiconductor nanostructures overlap respective lower ones of the plurality of semiconductor nanostructures; a gate stack comprising a bottom portion underlying a bottommost semiconductor nanostructure of the plurality of semiconductor nanostructures, wherein the bottom portion comprises a first work-function layer; and a second work-function layer encircled by the first work-function layer, wherein all layers in the bottom portion has a first total count; and an upper portion between two neighboring ones of the plurality of semiconductor nanostructures, wherein the upper portion comprises the second work-function layer, and wherein all layers in the upper portion have a second total count smaller than the first total count; and a semiconductor region aside of, and contacting, the plurality of semiconductor nanostructures. In an embodiment, the upper portion of the gate stack is free from the second work-function layer. In an embodiment, a first height of the bottom portion is higher than a second height of the upper portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
depositing a multilayer stack comprising a plurality of sacrificial layers and a plurality of semiconductor layers located alternatingly, wherein the plurality of sacrificial layers comprise:
a bottom sacrificial layer having a first thickness; and
upper sacrificial layers over the bottom sacrificial layer, wherein the upper sacrificial layers have second thicknesses smaller than the first thickness;
patterning the multilayer stack to form a first protruding fin;
forming a first dummy gate stack on the first protruding fin;
forming a first source/drain region aside of the first dummy gate stack;
removing the first dummy gate stack and the plurality of sacrificial layers in the first protruding fin to leave first recesses, wherein the first recesses comprise:
a bottom recess below a bottommost semiconductor layer of the plurality of semiconductor layers in the first protruding fin, wherein the forming the first replacement gate stack comprises depositing a first work-function layer and depositing a second work-function layer into the bottom recess; and
upper recesses higher than the bottommost semiconductor layer, wherein the first replacement gate stack comprises the first work-function layer in the upper recesses; and
forming a first replacement gate stack in the first recesses, wherein a ratio of the first thickness to one of the second thicknesses is greater than about 1.2.
